(19) United States
(12) Patent Application Publication
(10) Pub. No.: US 2026/0322063 A1
(43) Pub. Date: Oct. 15, 2026

(54) LASER SYSTEM, ADJUSTMENT METHOD OF LASER SYSTEM, AND ELECTRONIC DEVICE MANUFACTURING METHOD

(71) Applicant: Gigaphoton Inc., Tochigi (JP)

(72) Inventor: Masakazu MIYATA, Tochigi (JP)

(73) Assignee: Gigaphoton Inc., Tochigi (JP)

(21) Appl. No.: 19/554,727

(22) Filed: Mar. 3, 2026

(30) Foreign Application Priority Data
Apr. 9, 2025 (JP) 2025-064530

(51) Int. Cl. H01S 3/097; G03F 7/00; G03F 7/20; H01S 3/225; H01S 3/23

(52) U.S. Cl. CPC H01S 3/09702; G03F 7/2004; G03F 7/70025; G03F 7/70041; H01S 3/225; H01S 3/2308

(57) ABSTRACT

A laser system includes an oscillation-stage laser device including a first pulse compression circuit, an amplification-stage laser device including a second pulse compression circuit, and a processor. The processor determines a timing difference from when a first switch included in the first pulse compression circuit and having a first delay characteristic is turned on until when a second switch included in the second pulse compression circuit and having a second delay characteristic is turned on, and controls an output timing of each of a first oscillation trigger signal input to the first pulse compression circuit and a second oscillation trigger signal input to the second pulse compression circuit. When one of the first switch and the second switch is replaced with a third switch having a third delay characteristic, the processor corrects the output timing of at least one of the first and second oscillation trigger signals.

### CROSS-REFERENCE TO RELATED APPLICATIONS

The present application claims the benefit of Japanese Patent Application No. 2025-064530, filed on Apr. 9, 2025, the entire contents of which are hereby incorporated by reference.

### BACKGROUND

### 1. Technical Field

The present disclosure relates to a laser system, an adjustment method of a laser system, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. A gas laser device with a line-narrowed spectral line width is referred to as a line narrowing gas laser device.

### LIST OF DOCUMENTS

### Patent Documents

Patent Document 1: Japanese Patent Application Publication No. 2005-252147

Patent Document 2: Japanese Patent Application Publication No. 2010-092892

### SUMMARY

A laser system according to an aspect of the present disclosure includes an oscillation-stage laser device including a first pulse compression circuit, an amplification-stage laser device including a second pulse compression circuit, and a processor. The processor is configured to determine a timing difference from when a first switch included in the first pulse compression circuit and having a first delay characteristic is turned on until when a second switch included in the second pulse compression circuit and having a second delay characteristic is turned on, and control an output timing of each of a first oscillation trigger signal to be input to the first pulse compression circuit and a second oscillation trigger signal to be input to the second pulse compression circuit so that the oscillation-stage laser device and the amplification-stage laser device are synchronized with each other. When one of the first switch and the second switch is replaced with a third switch having a third delay characteristic, the processor corrects the output timing of at least one of the first oscillation trigger signal and the second oscillation trigger signal to suppress change of the timing difference.

An adjustment method of a laser system, according to an aspect of the present disclosure, including an oscillation-stage laser device including a first pulse compression circuit and an amplification-stage laser device including a second pulse compression circuit, includes determining a timing difference from when a first switch included in the first pulse compression circuit and having a first delay characteristic is turned on until when a second switch included in the second pulse compression circuit and having a second delay characteristic is turned on so that the oscillation-stage laser device and the amplification-stage laser device are synchronized with each other; and when one of the first switch and the second switch is replaced with a third switch having a third delay characteristic, correcting an output timing of at least one of a first oscillation trigger signal to be input to the first pulse compression circuit and a second oscillation trigger signal to be input to the second pulse compression circuit to suppress change of the timing difference.

An electronic device manufacturing method according to an aspect of the present disclosure includes generating pulse laser light using a laser system, outputting the pulse laser light to an exposure apparatus, and exposing a photosensitive substrate to the pulse laser light in the exposure apparatus to manufacture an electronic device. Here, the laser system includes an oscillation-stage laser device including a first pulse compression circuit, an amplification-stage laser device including a second pulse compression circuit, and a processor. The processor is configured to determine a timing difference from when a first switch included in the first pulse compression circuit and having a first delay characteristic is turned on until when a second switch included in the second pulse compression circuit and having a second delay characteristic is turned on, and control an output timing of each of a first oscillation trigger signal to be input to the first pulse compression circuit and a second oscillation trigger signal to be input to the second pulse compression circuit so that the oscillation-stage laser device and the amplification-stage laser device are synchronized with each other. When one of the first switch and the second switch is replaced with a third switch having a third delay characteristic, the processor corrects the output timing of at least one of the first oscillation trigger signal and the second oscillation trigger signal to suppress change of the timing difference.

### BRIEF DESCRIPTION OF THE DRAWINGS

An embodiment of the present disclosure will be described below merely as an example with reference to the accompanying drawings.

FIG. 1 shows the configuration of an exposure system in a comparative example.

FIG. 2 shows the configuration of a laser system shown in FIG. 1.

FIG. 3 shows the configuration of a power source device including chargers and pulse power modules shown in FIG. 2.

FIG. 4 is a timing chart showing oscillation trigger signals and turn-on timings of switches SW1, SW2 in the comparative example.

FIG. 5 shows characteristics of delay times of the switches SW1, SW2.

FIG. 6 is a timing chart when the switch SW2 in the comparative example is replaced with a switch SW3 having a delay time characteristic different from that of the switch SW1.

FIG. 7 is a flowchart showing the procedure of synchronization control of the laser system in an embodiment.

FIG. 8 shows the characteristics of the delay times of the switches SW1, SW2 with a part of a characteristic of a delay time of a switch SW3 superimposed thereto.

FIG. 9 shows an example of difference data created in S7 of FIG. 7.

FIG. 10 is a flowchart showing the procedure of correction control of output timings of the oscillation trigger signals in the embodiment.

### DESCRIPTION OF EMBODIMENTS

### Contents

1. Comparative example
   1.1 Exposure system
   1.2 Exposure apparatus 200
   1.3 Laser system 100
      1.3.1 Configuration
      1.3.2 Operation
   1.4 Power source device
      1.4.1 Configuration
      1.4.2 Operation
2. Problem of comparative example
3. Laser system 100 re-correcting output timing of oscillation trigger signal
   3.1 Overview
   3.2 Operation
   3.3 Effect
4. Others
   4.1 Processor
   4.2 Supplement

Hereinafter, an embodiment of the present disclosure will be described in detail with reference to the drawings. The embodiment described below shows examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Comparative Example

### 1.1 Exposure System

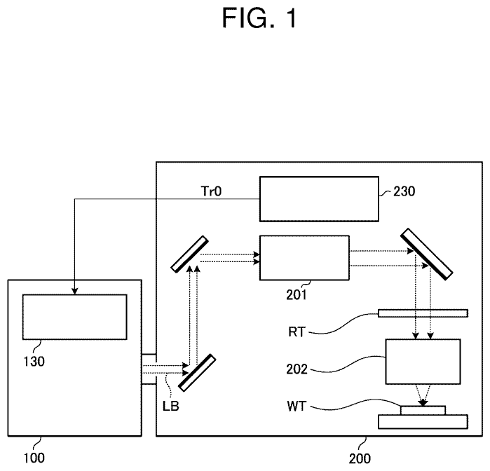

FIG. 1 shows the configuration of an exposure system in a comparative example. The comparative example of the present disclosure is an example recognized by the applicant as known only by the applicant, and is not a publicly known example admitted by the applicant.

The exposure system includes a laser system 100 and an exposure apparatus 200. In FIG. 1, the laser system 100 is shown in a simplified manner. The laser system 100 includes a laser control processor 130 and is configured to output pulse laser light LB toward the exposure apparatus 200.

### 1.2 Exposure Apparatus 200

As shown in FIG. 1, the exposure apparatus 200 includes an illumination optical system 201, a projection optical system 202, and an exposure control processor 230. The exposure control processor 230 transmits an oscillation command Tr0 to the laser control processor 130 and controls the entire exposure apparatus 200. The illumination optical system 201 illuminates a reticle pattern of a reticle (not shown) arranged on a reticle stage RT with the pulse laser light LB incident from the laser system 100. The projection optical system 202 causes the pulse laser light LB transmitted through the reticle to be imaged as being reduced and projected on a workpiece (not shown) arranged on a workpiece table WT. The workpiece is a photosensitive substrate such as a semiconductor wafer on which photoresist is applied.

The exposure control processor 230 synchronously translates the reticle stage RT and the workpiece table WT, so that the exposure apparatus 200 exposes the workpiece to the pulse laser light LB reflecting the reticle pattern. After the reticle pattern is transferred onto the semiconductor wafer by the exposure process described above, an electronic device can be manufactured through a plurality of processes.

### 1.3 Laser System 100

### 1.3.1 Configuration

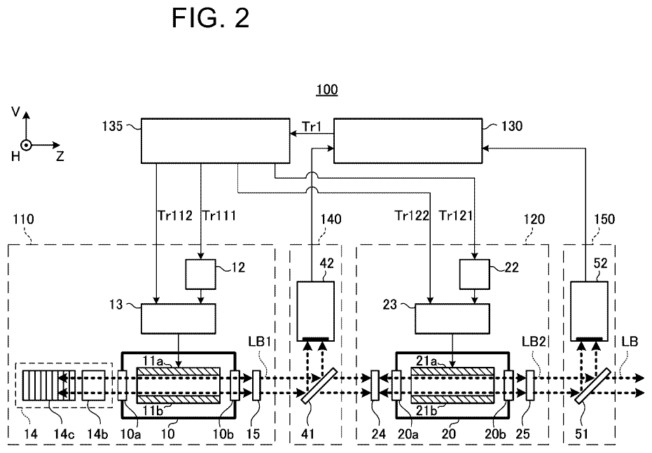

FIG. 2 shows the configuration of the laser system 100 shown in FIG. 1. The laser system 100 includes an oscillation-stage laser device 110, an amplification-stage laser device 120, the laser control processor 130, a synchronization processor 135, and monitor modules 140, 150. The oscillation-stage laser device 110 includes a laser chamber 10, a charger 12, a pulse power module 13, a line narrowing module 14, and an output mirror 15. The pulse power module 13 corresponds to the first pulse compression circuit in the present disclosure. The output mirror 15 and a grating 14c included in the line narrowing module 14 configure an optical resonator.

The laser chamber 10 includes windows 10a, 10b, and is arranged such that the windows 10a, 10b are located on the optical path of the optical resonator. The laser chamber 10 is configured to accommodate a laser gas including components of a laser gain medium, and includes a pair of electrodes 11a, 11b that apply a voltage to the laser gain medium. The laser gain medium is, for example, ArF or KrF.

The travel direction of pulse laser light LB1 output from the output mirror 15 is represented by a Z direction. The direction in which the electrodes 11a, 11b face each other is represented by a V direction or a-V direction. The Z direction and the V direction are perpendicular to each other, and the direction perpendicular to both of them is represented by an H direction or a-H direction. In FIG. 2, the configuration of the laser system 100 is shown as viewed in the-H direction.

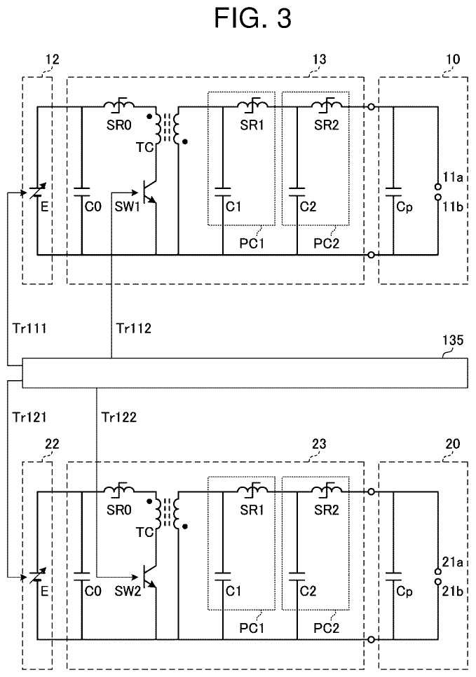

The pulse power module 13 includes a main capacitor C0 and a switch SW1 which will be described later with reference to FIG. 3. The switch SW1 corresponds to the first switch in the present disclosure, and is a solid-state switch such as an insulated gate bipolar transistor (IGBT) switch, a bipolar junction transistor (BJT) switch, a thyristor switch, or the like. The main capacitor C0 is connected to the charger 12 and the switch SW1 is connected to the synchronization processor 135. Output terminals of the pulse power module 13 are connected to the electrodes 11a, 11b.

The line narrowing module 14 includes a prism 14b and the grating 14c. The prism 14b is arranged on the optical path of light output from the window 10a. The prism 14b is rotatable about an axis parallel to the V direction by a rotation stage (not shown). The grating 14c is arranged on the optical path of the light having transmitted through the prism 14b. The output mirror 15 is configured by a partial reflection mirror.

The monitor module 140 includes a beam splitter 41 and an optical sensor 42. The beam splitter 41 is arranged on the optical path of the pulse laser light LB1 output from the output mirror 15, and is configured to transmit a part of the pulse laser light LB1 at a high transmittance, and to reflect another part thereof. The optical sensor 42 is arranged on the optical path of the pulse laser light LB1 reflected by the beam splitter 41.

The amplification-stage laser device 120 includes a laser chamber 20, a charger 22, a pulse power module 23, a rear mirror 24, and an output mirror 25. The pulse power module 23 corresponds to the second pulse compression circuit in the present disclosure. The rear mirror 24 and the output mirror 25 configure an optical resonator. The rear mirror 24 is configured by a partial reflection mirror having a higher reflectance than the output mirror 25, and is arranged on the optical path of the pulse laser light LB1. The configurations of the laser chamber 20, the charger 22, the pulse power module 23, and the output mirror 25 are similar to those of the laser chamber 10, the charger 12, the pulse power module 13, and the output mirror 15, respectively. The configurations of windows 20a, 20b and a pair of electrodes 21a, 21b included in the laser chamber 20 are similar to those of the windows 10a, 10b and the electrodes 11a, 11b, respectively.

The monitor module 150 is arranged on the optical path of pulse laser light LB2 output from the output mirror 25. The configurations of the beam splitter 51 and the optical sensor 52 included in the monitor module 150 are similar to those of the beam splitter 41 and the optical sensor 42, respectively.

### 1.3.2 Operation

The laser control processor 130 receives the oscillation command Tr0 from the exposure control processor 230. The laser control processor 130 transmits a trigger signal Tr1 to the synchronization processor 135 based on the oscillation command Tr0. The synchronization processor 135 transmits charge start signals Tr111, Tr121 to the chargers 12, 22, respectively, based on the trigger signal Tr1, and then transmits oscillation trigger signals Tr112, Tr122 to the pulse power modules 13, 23, respectively. The oscillation trigger signals Tr112, Tr122 correspond to the first and second oscillation trigger signals, respectively, in the present disclosure.

In the oscillation-stage laser device 110, the charger 12 starts charging the main capacitor C0 upon receiving the charge start signal Tr111 from the synchronization processor 135. The switch SW1 included in the pulse power module 13 is turned on when the oscillation trigger signal Tr112 is received from the synchronization processor 135. When the switch SW1 is turned on, the pulse power module 13 generates a pulse high voltage from the electric energy charged in the main capacitor C0, and applies the high voltage to the electrodes 11a, 11b.

When the high voltage is applied to the electrodes 11a, 11b, discharge occurs between the electrodes 11a, 11b. The laser gas in the laser chamber 10 is excited by the energy of the discharge, and shifts to a high energy level. When the excited laser gas then shifts to a low energy level, light having a wavelength corresponding to the difference between the energy levels is emitted.

The light generated in the laser chamber 10 is output to the outside of the laser chamber 10 through the windows 10a, 10b. The beam width of the light output from the window 10a is expanded by the prism 14b in a plane parallel to an HZ plane. The light transmitted through the prism 14b is incident on the grating 14c.

The light incident on the grating 14c is reflected by a plurality of grooves of the grating 14c and is diffracted in a direction corresponding to the wavelength of the light. By matching the incident angle of the light incident on the grating 14c with the diffraction angle of the diffracted light having a desired wavelength, the wavelength of the diffracted light returning to the prism 14b from the grating 14c is selected. In accordance with the change of posture of the prism 14b due to the rotation angle of the rotation stage, the incident angle of the light incident on the grating 14c changes, and the wavelength selected by the line narrowing module 14 changes. The prism 14b reduces the beam width in the HZ plane of the diffracted light returning from the grating 14c and returns the light to the inside of the laser chamber 10 through the window 10a.

The output mirror 15 transmits and outputs a part of the light output from the window 10b, and reflects another part thereof back into the laser chamber 10.

In this way, the light output from the laser chamber 10 reciprocates between the line narrowing module 14 and the output mirror 15. The light is amplified every time it passes through a discharge space between the electrodes 11a, 11b, and is line-narrowed every time the light is turned back by the line narrowing module 14. Thus, the light having undergone laser oscillation and line narrowing is output as the pulse laser light LB1 from the output mirror 15.

The monitor module 140 transmits a signal indicating the emission timing of the pulse laser light LB1 to the laser control processor 130. The emission timing of the pulse laser light LB1 substantially corresponds to the timing at which the switch SW1 included in the pulse power module 13 is turned on. The monitor module 140 also measures the pulse energy and the beam profile of the pulse laser light LB1.

The pulse laser light LB1 output from the oscillation-stage laser device 110 enters the laser chamber 20 via the rear mirror 24 and the window 20a. The timing at which the oscillation trigger signal Tr122 is input to the switch SW2 (see FIG. 3) of the pulse power module 23 is controlled so that discharge is started between the electrodes 21a, 21b at the timing at which the pulse laser light LB1 enters the laser chamber 20. The switch SW2 corresponds to the second switch in the present disclosure. The pulse laser light LB1 reciprocates between the rear mirror 24 and the output mirror 25. This light is amplified every time it passes through the discharge space between the electrodes 21a, 21b, and is output as the pulse laser light LB2 from the output mirror 25.

The amplification-stage laser device 120 amplifies the pulse energy while maintaining the spectrum of the pulse laser light LB1 line-narrowed by the oscillation-stage laser device 110. Accordingly, the laser system 100 can achieve line-narrowing and high power output.

The monitor module 150 transmits a signal indicating the emission timing of the pulse laser light LB2 to the laser control processor 130. The emission timing of the pulse laser light LB2 substantially corresponds to the timing at which the switch SW2 included in the pulse power module 23 is turned on. The monitor module 150 also measures the pulse energy and the beam profile of the pulse laser light LB2.

The pulse laser light LB having passed through the monitor module 150 enters the exposure apparatus 200.

### 1.4 Power Source Device

### 1.4.1 Configuration

FIG. 3 shows the configuration of the power source device including the chargers 12, 22 and the pulse power modules 13, 23 shown in FIG. 2. The charger 12 includes a DC variable power source E. In addition to the main capacitor C0 and the switch SW1, the pulse power module 13 includes a step-up transformer TC, magnetic switches SR0, SR1, SR2, and first and second transfer capacitors C1, C2. The output terminals of the pulse power module 13 are connected to a peaking capacitor Cp and the electrodes 11a, 11b which are connected in parallel to each other. The peaking capacitor Cp and the electrodes 11a, 11b are included in the laser chamber 10.

Each of the magnetic switches SR0 to SR2 includes a saturable reactor. Each of the magnetic switches SR0 to SR2 is configured to switch into a low-impedance state when a time integration value of the voltage applied between both ends thereof reaches a predetermined value determined by characteristics of each magnetic switch.

One terminal of the main capacitor C0 is connected to the DC variable power source E and one terminal of the magnetic switch SR0. The other terminal of the main capacitor C0 is connected to the reference potential. The other terminal of the magnetic switch SR0 is connected to the reference potential via a primary winding of the step-up transformer TC and the switch SW1 which are connected in series with each other.

One terminal of the magnetic switch SR1 is connected to the reference potential via a secondary winding of the step-up transformer TC and is connected to one terminal of the first transfer capacitor C1. The other terminal of the first transfer capacitor C1 is connected to the reference potential. That is, the secondary winding of the step-up transformer TC and the first transfer capacitor C1 are connected in parallel to each other. The first transfer capacitor C1 and the magnetic switch SR1 configure a first magnetic pulse compression circuit PC1.

The other terminal of the magnetic switch SR1 is connected to one terminal of the magnetic switch SR2 and is connected to one terminal of the second transfer capacitor C2. The other terminal of the second transfer capacitor C2 is connected to the reference potential. The second transfer capacitor C2 and the magnetic switch SR2 configure a second magnetic pulse compression circuit PC2.

The other terminal of the magnetic switch SR2 is connected to one terminal of the peaking capacitor Cp and the electrode 11a. The other terminal of the peaking capacitor Cp and the electrode 11b are connected to the reference potential.

### 1.4.2 Operation

When the charger 12 receives the charge start signal Tr111 from the synchronization processor 135, the main capacitor C0 is charged by the DC variable power source E. When the switch SW1 is turned on as receiving the oscillation trigger signal Tr112 from the synchronization processor 135, the voltage of the main capacitor C0 is applied to the magnetic switch SR0. When the time integration value of the voltage applied to the magnetic switch SR0 becomes a predetermined value, the magnetic switch SR0 is turned on, and a pulse current flows from the main capacitor C0 through the magnetic switch SR0, the primary winding of the step-up transformer TC, and the switch SW1.

When the current flows through the primary winding of the step-up transformer TC, a current corresponding to the winding ratio of the step-up transformer TC flows through the secondary winding of the step-up transformer TC due to electromagnetic induction. When a current flows through the secondary winding of the step-up transformer TC, the first transfer capacitor C1 is charged and the voltage of the first transfer capacitor C1 is applied to the magnetic switch SR1. When the time integration value of the voltage applied to the magnetic switch SR1 becomes a predetermined value, the magnetic switch SR1 is turned on, and a pulse current flows through the magnetic switch SR1.

When the current flows through the magnetic switch SR1, charge in the first transfer capacitor C1 is transferred to the second transfer capacitor C2, so that the second transfer capacitor C2 is charged and the voltage of the second transfer capacitor C2 is applied to the magnetic switch SR2. The pulse width of the current at the time of charging the second transfer capacitor C2 is shorter than the pulse width of the current at the time of charging the first transfer capacitor C1, and the voltage is increased. When the time integration value of the voltage applied to the magnetic switch SR2 becomes a predetermined value, the magnetic switch SR2 is turned on, and a pulse current flows through the magnetic switch SR2.

When the current flows through the magnetic switch SR2, charge in the second transfer capacitor C2 is transferred to the peaking capacitor Cp, and the peaking capacitor Cp is charged. The pulse width of the current at the time of charging the peaking capacitor Cp is shorter than the pulse width of the current at the time of charging the second transfer capacitor C2, and the voltage is increased.

When the voltage of the peaking capacitor Cp reaches a breakdown voltage of the laser gas, discharge occurs between the electrodes 11a, 11b. As a result, the laser gas is excited and laser oscillation occurs. When switching operation of the switch SW1 is performed at a predetermined repetition frequency, the pulse laser light LB1 is output at the repetition frequency.

The configuration and operation of the charger 22 and the pulse power module 23 are similar to those of the charger 12 and the pulse power module 13. Here, the pulse power module 23 includes a switch SW2.

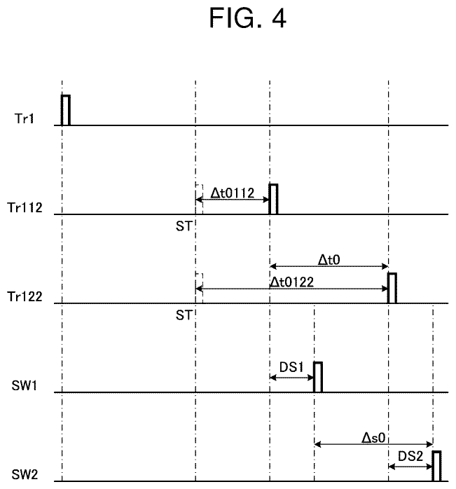

FIG. 4 is a timing chart showing the oscillation trigger signals Tr112, Tr122 and turn-on timings of the switches SW1, SW2 in the comparative example. Each of the dash-dot lines in the vertical direction in FIG. 4 indicates that timings of events connected by the dash-dot line are the same. After receiving the trigger signal Tr1, the synchronization processor 135 outputs the charge start signals Tr111, Tr121 (not shown in FIG. 4), and then outputs the oscillation trigger signals Tr112, Tr122. Output timings of the oscillation trigger signals Tr112, Tr122 are determined by adding correction times Δt0112, Δt0122 to reference time ST, respectively. The reference time ST is set as the time when a sufficient time has elapsed for the chargers 12, 22 having received the charge start signals Tr111, Tr121 to charge the corresponding main capacitors C0, respectively. The synchronization processor 135 controls the output timings of the oscillation trigger signals Tr112, Tr122 so that synchronization between the oscillation-stage laser device 110 and the amplification-stage laser device 120 is optimized.

Adjustment oscillation is performed before the laser system 100 is put into actual operation. The adjustment oscillation is a process of performing laser oscillation while changing the time difference between the correction times Δt0112, Δt0122, and determining, as the synchronization time difference Δt0, the time difference when measurement results of the pulse energy and the beam profile of the pulse laser light LB1, LB2 become in the optimum condition.

The synchronization time difference Δt0 is a critical control parameter for optimizing the relationship between the timing at which the pulse laser light LB1 enters the laser chamber 20 and the timing at which discharge is started between the electrodes 21a, 21b. A timing difference Δs0 between turn-on timings of the switches SW1, SW2 defines the relationship more directly. If a delay time DS1 from when the switch SW1 receives the oscillation trigger signal Tr112 to when the switch SW1 is turned on and a delay time DS2 from when the switch SW2 receives the oscillation trigger signal Tr122 to when the switch SW2 is turned on are always the same, the timing difference Δs0 is always the same as the synchronization time difference Δt0. If the timing difference Δs0 is always the same as the synchronization time difference Δt0, the oscillation-stage laser device 110 and the amplification-stage laser device 120 can be appropriately synchronized by determining the synchronization time difference Δt0.

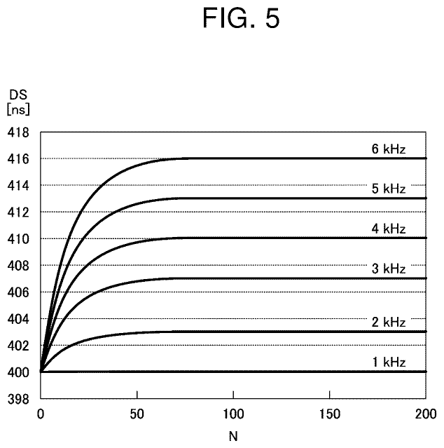

FIG. 5 shows characteristics of the delay times DS1, DS2 of the switches SW1, SW2. The characteristics of the delay times DS1, DS2 correspond to the first and second delay characteristics in the present disclosure, respectively. The horizontal axis of FIG. 5 indicates the number of pulses N from the first pulse of the pulse laser light LB continuously output from the laser system 100, and the vertical axis indicates the delay time DS. The delay time DS corresponds to each of the delay times DS1, DS2 of the switches SW1, SW2.

The delay time DS may vary with the number of pulses N from the first pulse, and the manner of change may vary with the repetition frequency of the pulse laser light LB. For example, the delay time DS tends to increase as the number of pulses N from the first pulse increases, and as the number of pulses N further increases, the amount of change in the delay time DS decreases and the delay time DS tends to converge to a substantially constant value. Further, for example, as the repetition frequency of the pulse laser light LB increases, the amount of change in the delay time DS corresponding to the change in the number of pulses N tends to increase, and the delay time DS when converging to a constant value tends to increase. When the pulse laser light LB is newly output after the oscillation pause in which the pulse laser light LB is not output for a certain period, the number of pulses N returns to 1 and the delay time DS returns to an initial value.

As shown in FIG. 5, the delay time DS changes during operation even with the same switch. Since the delay times DS1, DS2 of the switches SW1, SW2 must be the same including the properties of such changes, switches of the same model number are used for the switches SW1, SW2.

### 2. Problem of Comparative Example

The pulse power modules 13, 23 are replaced due to the expiration of their service life or deterioration in performance. The timing of the replacement may be different between the pulse power module 13 and the pulse power module 23. In the case of replacing the pulse power module 23, for example, it is preferably replaced with a new pulse power module 23 including a switch SW2 that has the same model number as the switch SW1 of the pulse power module 13.

However, the switch SW2 having the same model number as the switch SW1 may not be available due to, for example, discontinuation of production. In this case, preventing synchronization shift between the oscillation-stage laser device 110 and the amplification-stage laser device 120 requires replacing the pulse power module 13 in addition to the pulse power module 23 to ensure the switch model numbers are identical, potentially causing the additional cost.

The embodiment described below relates to properly synchronizing the oscillation-stage laser device 110 and the amplification-stage laser device 120 even if the characteristics of the delay time of the switches included in the pulse power modules 13, 23 are different.

### 3. Laser system 100 re-correcting output timing of oscillation trigger signal

### 3.1 Overview

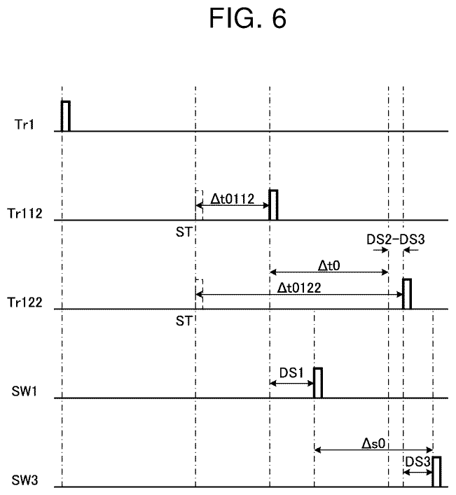

FIG. 6 is a timing chart when the switch SW2 in the comparative example is replaced with a switch SW3 having a delay time characteristic different from that of the switch SW1. Even if the switch SW2 is replaced with the switch SW3, it is preferable that the timing difference Δs0 of the turn-on timings of the switches SW1, SW3 is the same as the timing difference Δs0 (see FIG. 4) before the replacement. Therefore, in the embodiment, the correction time Δt0122 for outputting the oscillation trigger signal Tr122 is re-corrected in accordance with a delay time DS3 of the switch SW3. The switch SW3 corresponds to the third switch in the present disclosure, and the characteristic of the delay time DS3 corresponds to the third delay characteristic in the present disclosure.

The configuration of the laser system 100 in the embodiment is similar to that of the comparative example.

### 3.2 Operation

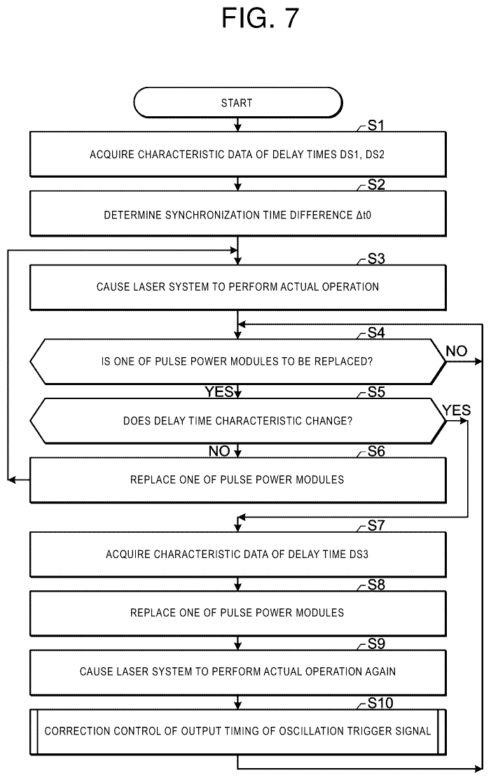

FIG. 7 is a flowchart showing the procedure of synchronization control of the laser system 100 in the embodiment.

In S1, the laser control processor 130 acquires characteristic data of the delay times DS1, DS2 of the switches SW1, SW2 before the replacement. The characteristics of the delay times DS1, DS2 do not need to be measured while the switches SW1, SW2 are mounted on the laser system 100, and may be measured as being connected to a measurement instrument (not shown). Here, the characteristic of the delay time of another switch having the same model number as that of the switch SW1, SW2 may be acquired.

In S2, the laser control processor 130 and the synchronization processor 135 perform the adjustment oscillation, and determine the synchronization time difference Δt0 so that the synchronization between the oscillation-stage laser device 110 and the amplification-stage laser device 120 is optimized. This process is similar to that of the comparative example. By determining the synchronization time difference Δt0, the timing difference Δs0 of the turn-on timings of the switches SW1, SW2 is determined.

In S3, the laser control processor 130 and the synchronization processor 135 cause the laser system 100 to perform actual operation. Here, for example, in accordance with FIG. 4, synchronization control is performed using the correction times Δt0112, Δt0122 corresponding to the synchronization time difference Δt0.

In S4, the laser control processor 130 determines the expiration of the service life and deterioration in performance of the pulse power modules 13, 23, and determines whether to replace one thereof.

If neither of the pulse power modules 13, 23 is replaced (S4: NO), the laser control processor 130 waits until it is determined to be YES in S4 while operating the laser system 100. Here, when the laser system 100 is stopped separately from the determination in S4, processing of the present flowchart may be ended.

If one of the pulse power modules 13, 23 is to be replaced (S4: YES), the laser control processor 130 determines whether the delay time characteristic changes in S5. For example, if the pulse power module 23 is to be replaced, it is determined whether the switch SW2 having mounted on the pulse power module 23 is different from the switch SW3 to be newly mounted in the delay time characteristic.

If the delay time characteristic does not change (S5: NO), one of the pulse power modules 13, 23 is replaced in S6. During the replacement operation, operation of the laser system 100 is stopped. After S6, in S3, the laser control processor 130 and the synchronization processor 135 causes the laser system 100 to perform actual operation again.

If the delay time characteristic changes (S5: YES), in S7, the laser control processor 130 acquires the characteristic data of the delay time DS3 of the newly mounted switch SW3. The laser control processor 130 further generates difference data between the characteristic of the delay time DS2 of the switch SW2 to be replaced and the characteristic of the delay time DS3 of the switch SW3.

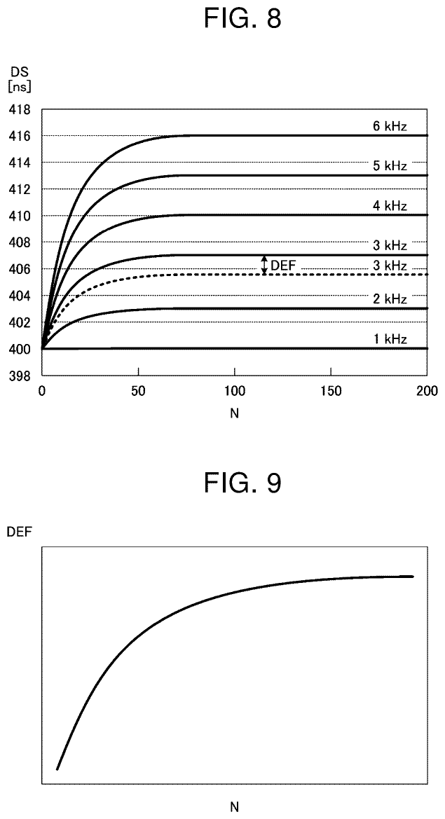

FIG. 8 shows the characteristics of the delay times DS1, DS2 of the switches SW1, SW2 with a part of the characteristic of the delay time DS3 of the switch SW3 superimposed thereto. In FIG. 8, the characteristic of the delay time DS3 at 3 kHz is indicated by a dashed line. The difference between the delay times when the repetition frequency is the same and the number of pulses N from the first pulse is also the same is defined as a difference DEF.

FIG. 9 shows an example of the difference data created in S7 of FIG. 7. The horizontal axis of FIG. 9 indicates the number of pulses N from the first pulse, and the vertical axis indicates the difference DEF. The difference data may be created for each repetition frequency and for each number of pulses N, and the difference data may be held in a table format.

Referring back to FIG. 7, in S8, one of the pulse power modules 13, 23 is replaced. During the replacement operation, operation of the laser system 100 is stopped. After S8, in S9, the laser control processor 130 and the synchronization processor 135 causes the laser system 100 to perform actual operation again.

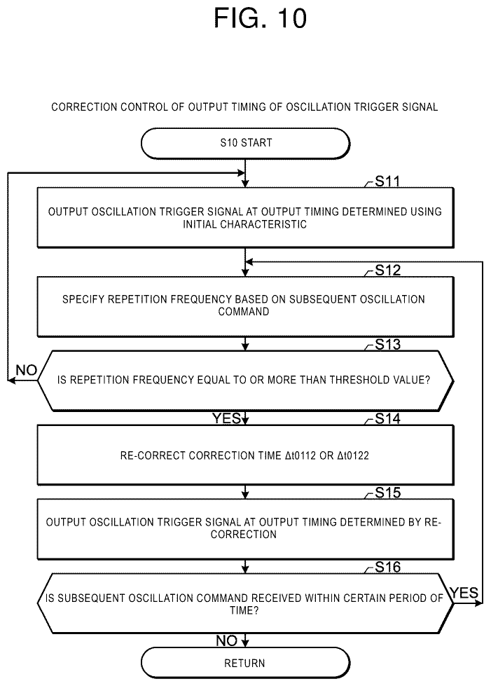

In S10, the laser control processor 130 and the synchronization processor 135 perform correction control of the output timings of the oscillation trigger signals Tr112, Tr122, and perform synchronization control in the laser system 100 including the switches SW1, SW3 having different delay time characteristics. This process will be described later with reference to FIG. 10.

After S10, the laser control processor 130 waits until it is determined to be YES in S4 while operating the laser system 100. Since the synchronization time difference Δt0 does not need to be reset even if one of the pulse power modules 13, 23 is replaced, it is not necessary to return to S2. When the laser system 100 is stopped separately from the determination of S4, processing of the present flowchart may be ended.

FIG. 10 is a flowchart showing the procedure of correction control of the output timings of the oscillation trigger signals Tr112, Tr122 in the embodiment. The processes shown in FIG. 10 correspond to the subroutine of S10 of FIG. 7.

In S11, when the laser control processor 130 receives the oscillation command Tr0 from the exposure control processor 230, the synchronization processor 135 outputs the oscillation trigger signals Tr112, Tr122 at output timings determined using a corresponding initial characteristic. The initial characteristic is, for example, the difference DEF when the number of pulses N of the difference data shown in FIG. 9 is 1. The initial characteristic is a characteristic that reflects the difference between the characteristic data of the delay time DS2 of the replaced switch SW2 and the characteristic data of the delay time DS3 of the switch SW3, but that does not depend on the repetition frequency.

In S12, the synchronization processor 135 specifies the repetition frequency based on the difference between the time of the subsequent oscillation command Tr0 and the time of the immediately preceding oscillation command Tr0. The immediately preceding oscillation command Tr0 corresponds to the first oscillation command in the present disclosure, and the subsequent oscillation command Tr0 corresponds to the second oscillation command in the present disclosure. Here, the inverse of the time interval of the latest oscillation command Tr0 is set as the repetition frequency, and the repetition frequency is reflected in the re-correction in S14, so that the change in the time interval of the oscillation command Tr0 can be immediately coped with.

In S13, the synchronization processor 135 determines whether the repetition frequency is equal to or more than a threshold value. For example, if the repetition frequency is equal to or more than 100 Hz, the repetition frequency is determined to be equal to or more than the threshold value. If the repetition frequency is less than the threshold value (S13: NO), processing returns to S11 and the oscillation trigger signals Tr112, Tr122 are output at timings determined using the initial characteristics. If the repetition frequency is equal to or more than the threshold value (S13: YES), processing proceeds to S14.

In S14, the synchronization processor 135 re-corrects the correction time Δt0112 or Δt0122 using the delay time DS obtained by applying the repetition frequency and the number of pulses N to the difference data. For example, if the pulse power module 23 is replaced with the pulse power module including the switch SW3, a value DS2-DS3 obtained by subtracting the delay time DS3 of the switch SW3 from the delay time DS2 of the switch SW2 is added to the current correction time Δt0122 (see FIG. 4) to obtain a new correction time Δt0122 (see FIG. 6). Accordingly, it is possible to suppress variation of the timing difference Δs0 between turn-on timings of the switches SW1, SW3. Alternatively, by subtracting DS2-DS3 from the current correction time Δt0112, it is also possible to suppress variation of the timing difference Δs0 between the turn-on timings of the switches SW1, SW3. Here, DS2-DS3 is obtained from the difference data.

In S15, the synchronization processor 135 outputs the oscillation trigger signals Tr112, Tr122 at output timings determined using the correction times Δt0112, Δt0122. One of the correction times Δt0112, Δt0122 is the correction time re-corrected in S14.

In S16, the synchronization processor 135 determines whether or not the laser control processor 130 has received the subsequent oscillation command Tr0 within a certain period of time. The certain period of time may be, for example, 1 second. If the subsequent oscillation command Tr0 is received within the certain period of time (S16: YES), the synchronization processor 135 returns the process to S12. When the subsequent oscillation command Tr0 is not received within the certain period of time (S16: NO), the synchronization processor 135 ends the processes of the present flowchart.

Here, description has been provided on the case in which one of the correction times Δt0112, Δt0122 is corrected as creating the difference data, but the present disclosure is not limited thereto. The difference data may not be created, or both the correction times Δt0112, Δt0122 may be corrected. For example, when the pulse power module 23 including the switch SW2 is replaced with the pulse power module including the switch SW3, the delay time DS3 of the switch SW3 may be added to the current correction time Δt0112, and the delay time DS2 of the switch SW2 may be added to the current correction time Δt0122.In this case as well, it is possible to suppress variation of the timing difference Δs0 between turn-on timings of the switches SW1, SW3.

### 3.3 Effect

(1) According to the embodiment, the laser system 100 includes the oscillation-stage laser device 110 including the pulse power module 13, the amplification-stage laser device 120 including the pulse power module 23, and the laser control processor 130 or the synchronization processor 135. The laser control processor 130 or the synchronization processor 135 determines the timing difference Δs0 from when the switch SW1 included in the pulse power module 13 and having the first delay characteristic is turned on until then the switch SW2 included in the pulse power module 23 and having the second delay characteristic is turned on, and controls the output timing of each of the oscillation trigger signal Tr112 to be input to the pulse power module 13 and the oscillation trigger signal Tr122 to be input to the pulse power module 23 so that the oscillation-stage laser device 110 and the amplification-stage laser device 120 are synchronized with each other. When either the switch SW1 or the switch SW2 is replaced with the switch SW3 having the third delay characteristic, the laser control processor 130 or the synchronization processor 135 corrects the output timing of at least one of the oscillation trigger signals Tr112, Tr122 so that change of the timing difference Δs0 is suppressed.

According to the above, by correcting the output timing of the oscillation trigger signal Tr112 or Tr122 in accordance with the delay characteristics of the switches included in the pulse power modules 13, 23, it is possible to synchronize the oscillation-stage laser device 110 and the amplification-stage laser device 120 even when the switch having a different delay characteristic is used. When one of the switches of the oscillation-stage laser device 110 and the amplification-stage laser device 120 needs to be replaced, the other switch does not need to be replaced with a switch having the same characteristic, and the cost of maintenance can be reduced.

(2) According to the embodiment, each of the first delay characteristic, the second delay characteristic, and the third delay characteristic includes the relationship between the number of pulses N from the first pulse of the pulse laser light LB continuously output from the laser system 100 and the delay time DS from the output timing of the oscillation trigger signal Tr112 or Tr122 to the turn-on timing. The laser control processor 130 or the synchronization processor 135 corrects the output timing based on the number of pulses N.

According to the above, by correcting the output timing of the oscillation trigger signal Tr112 or Tr122 in accordance with the delay time DS that changes in accordance with the number of pulses N from the first pulse, it is possible to suppress the change of the timing difference Δs0 between the turn-on timings of the switches included in the pulse power modules 13, 23.

(3) According to the embodiment, when the repetition frequency of the pulse laser light LB is less than the threshold value, the laser control processor 130 or the synchronization processor 135 corrects the output timing of the oscillation trigger signal Tr112 or Tr122 using the delay time DS when the number of pulses N is set to a minimum value.

According to the above, when the repetition frequency is low and the delay time DS is not easily affected by the preceding pulse, it is possible to perform highly accurate correction by performing correction using the first pulse.

(4) According to the embodiment, each of the first delay characteristic, the second delay characteristic, and the third delay characteristic includes the relationship between the repetition frequency of the pulse laser light LB output from the laser system 100 and the delay time DS from the output timing of the oscillation trigger signal Tr112 or Tr122 to the turn-on timing. The laser control processor 130 or the synchronization processor 135 corrects the output timing based on the repetition frequency.

According to the above, by correcting the output timing of the oscillation trigger signal Tr112 or Tr122 in accordance with the delay time DS that changes in accordance with the repetition frequency of the pulse laser light LB, it is possible to suppress the change of the timing difference Δs0 between the turn-on timings of the switches included in the pulse power modules 13, 23.

(5) According to the embodiment, when the repetition frequency is less than the threshold value, the laser control processor 130 or the synchronization processor 135 corrects the output timing of the oscillation trigger signal Tr112 or Tr122 using the constant value independent from the repetition frequency.

According to the above, when the delay time DS is not easily affected by the preceding pulse, it is possible to perform highly accurate correction by performing correction using the constant value.

(6) According to the embodiment, the laser control processor 130 or the synchronization processor 135 receives the first oscillation command Tr0 for outputting the first pulse of the pulse laser light LB and the second oscillation command Tr0 for outputting the second pulse of the pulse laser light LB after the first pulse, and determines the repetition frequency based on the time difference between the first oscillation command Tr0 and the second oscillation command Tr0.

According to the above, by determining the repetition frequency based on the time difference between the first and second oscillation commands Tr0, Tr0, it is possible to perform appropriate correction even when the repetition frequency changes.

(7) According to the embodiment, the laser control processor 130 or the synchronization processor 135 corrects the output timing of the oscillation trigger signal Tr112 or Tr122 based on the time difference between the latest first and second oscillation commands Tr0, Tr0.

According to the above, by applying the correction based on the repetition frequency determined from the latest first and second oscillation commands Tr0, Tr0, it is possible to quickly perform appropriate correction even when the repetition frequency changes.

(8) According to the embodiment, the laser control processor 130 or the synchronization processor 135 corrects the output timing based on the number of pulses N and the repetition frequency.

According to the above, by correcting the output timing of the oscillation trigger signal Tr112 or Tr122 in accordance with the delay time DS that changes in accordance with both the number of pulses N from the first pulse and the repetition frequency of the laser light LB, it is possible to suppress the change of the timing difference Δs0 between the turn-on timings of the switches included in the pulse power modules 13, 23.

(9) According to the embodiment, the laser control processor 130 or the synchronization processor 135 corrects the output timing of the oscillation trigger signal Tr112 or Tr122, which is one of the oscillation trigger signal Tr112 and the oscillation trigger signal Tr122, corresponding to the switch SW1 or SW2 replaced with the switch SW3.

According to the above, by correcting the output timing of the oscillation trigger signal Tr112 or Tr122 for the switch replaced with the switch SW3, the output timing of the oscillation trigger signal Tr112 or Tr122 for the switch not replaced is maintained, and stable control can be performed.

(10) According to the embodiment, the laser control processor 130 or the synchronization processor 135 corrects the output timing of the oscillation trigger signal Tr112 or Tr122 based on the difference DEF between the third delay characteristic and the delay characteristic of the first or second delay characteristic of the switch SW1 or SW2 which is replaced with the switch SW3.

According to the above, by correcting the output timing of the oscillation trigger signal Tr112 or Tr122 based on the difference DEF of the delay characteristics of the old and new switches at the replacement, the timing difference Δs0 of the turn-on timings of the switches included in the pulse power modules 13, 23 is maintained before and after the replacement, and stable control can be performed.

(11) According to the embodiment, the laser control processor 130 or the synchronization processor 135 holds the difference DEF in a table format.

According to the above, the difference DEF of the delay characteristics of the old and new switches at the replacement is held in a table format, thereby reducing the computational burden and enabling quick control.

(12) In the embodiment, the laser control processor 130 or the synchronization processor 135 may correct the output timing of each of the oscillation trigger signals Tr112, Tr122.

According to the above, by correcting the output timing of each of the oscillation trigger signals Tr112, Tr122, it is possible to accurately reflect the delay characteristics of the two switches included in the oscillation-stage laser device 110 and the amplification-stage laser device 120.

In other respects, the embodiment is similar to the comparative example.

### 4. Others

### 4.1 Processor

The processor such as the laser control processor 130, the synchronization processor 135, and the exposure control processor 230 may be physically configured as hardware to execute various processes included in the present disclosure. For example, the processor may be a computer including a memory that stores a control program defining the various processes and a processing device that executes the control program. The control program may be stored in one memory, or may be stored separately in a plurality of memories at physically separate locations, and the various processes included may be defined by the control program as an aggregation thereof. The processing device may be a general-purpose processing device such as a CPU or a special-purpose processing device such as a GPU.

Alternatively, the processor may be programmed as software to execute the various processes included in the present disclosure. For example, the processor may be implemented in a dedicated device such as an ASIC or a programmable device such as an FPGA.

The various processes included in the present disclosure may be executed by one computer, one dedicated device, or one programmable device, or may be executed by cooperation of a plurality of computers, a plurality of dedicated devices, or a plurality of programmable devices at physically separate locations. The various processes may be executed by a combination including at least any two of: one or more computers, one or more dedicated devices, and one or more programmable devices.

### 4.2 Supplement

The description above is intended to be illustrative and the present disclosure is not limited thereto. Therefore, it would be obvious to those skilled in the art that various modifications to the embodiment of the present disclosure would be possible without departing from the spirit and the scope of the appended claims. Further, it would be also obvious to those skilled in the art that the embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A laser system comprising:
an oscillation-stage laser device including a first pulse compression circuit;
an amplification-stage laser device including a second pulse compression circuit; and
a processor configured to determine a timing difference from when a first switch included in the first pulse compression circuit and having a first delay characteristic is turned on until when a second switch included in the second pulse compression circuit and having a second delay characteristic is turned on, and control an output timing of each of a first oscillation trigger signal to be input to the first pulse compression circuit and a second oscillation trigger signal to be input to the second pulse compression circuit so that the oscillation-stage laser device and the amplification-stage laser device are synchronized with each other, and when one of the first switch and the second switch is replaced with a third switch having a third delay characteristic, correct the output timing of at least one of the first oscillation trigger signal and the second oscillation trigger signal to suppress change of the timing difference.

2. The laser system according to claim 1,
wherein each of the first delay characteristic, the second delay characteristic, and the third delay characteristic includes a relationship between a number of pulses from a first pulse of pulse laser light continuously output from the laser system and a corresponding delay time from the output timing to a turn-on timing, and
the processor corrects the at least one output timing based on the number of pulses.

3. The laser system according to claim 2,
wherein, when a repetition frequency of the pulse laser light is less than a threshold value, the processor corrects the at least one output timing using the delay time when the number of pulses is set to a minimum value.

4. The laser system according to claim 1,
wherein each of the first delay characteristic, the second delay characteristic, and the third delay characteristic includes a relationship between a repetition frequency of pulse laser light output from the laser system and a corresponding delay time from the output timing to a turn-on timing, and
the processor corrects the at least one output timing based on the repetition frequency.

5. The laser system according to claim 4,
wherein, when the repetition frequency is less than a threshold value, the processor corrects the at least one output timing using a constant value independent from the repetition frequency.

6. The laser system according to claim 4,
wherein the processor receives a first oscillation command for outputting a first pulse of the pulse laser light and a second oscillation command for outputting a second pulse of the pulse laser light subsequent to the first pulse, and determines the repetition frequency based on a time difference between the first oscillation command and the second oscillation command.

7. The laser system according to claim 6,
wherein the processor corrects the at least one output timing based on the time difference between the latest first and second oscillation commands.

8. The laser system according to claim 1,
wherein each of the first delay characteristic, the second delay characteristic, and the third delay characteristic includes a relationship among a number of pulses from a first pulse of pulse laser light continuously output from the laser system, a repetition frequency of the pulse laser light, and a corresponding delay time from the output timing to a turn-on timing, and
the processor corrects the at least one output timing based on the number of pulses and the repetition frequency.

9. The laser system according to claim 1,
wherein the processor corrects the output timing of an oscillation trigger signal, which is one of the first oscillation trigger signal and the second oscillation trigger signal, corresponding to the one of the first switch and the second switch which is replaced with the third switch.

10. The laser system according to claim 9,
wherein the processor corrects the output timing of the oscillation trigger signal, corresponding to the one of the first switch and the second switch which is replaced with the third switch, based on a difference between the third delay characteristic and a delay characteristic of the one of the first switch and the second switch which is replaced with the third switch, the delay characteristic being one of the first delay characteristic and the second delay characteristic.

11. The laser system according to claim 10,
wherein the processor holds data of the difference in a table format.

12. The laser system according to claim 1,
wherein the processor corrects the output timing of each of the first oscillation trigger signal and the second oscillation trigger signal.

13. An adjustment method of a laser system including an oscillation-stage laser device including a first pulse compression circuit and an amplification-stage laser device including a second pulse compression circuit, the method comprising:
determining a timing difference from when a first switch included in the first pulse compression circuit and having a first delay characteristic is turned on until when a second switch included in the second pulse compression circuit and having a second delay characteristic is turned on so that the oscillation-stage laser device and the amplification-stage laser device are synchronized with each other; and
when one of the first switch and the second switch is replaced with a third switch having a third delay characteristic, correcting an output timing of at least one of a first oscillation trigger signal to be input to the first pulse compression circuit and a second oscillation trigger signal to be input to the second pulse compression circuit to suppress change of the timing difference.

14. The adjustment method of a laser system according to claim 13,
wherein each of the first delay characteristic, the second delay characteristic, and the third delay characteristic includes a relationship between a number of pulses from a first pulse of pulse laser light continuously output from the laser system and a corresponding delay time from the output timing to a turn-on timing, and
the at least one output timing is corrected based on the number of pulses.

15. The adjustment method of a laser system according to claim 13,
wherein each of the first delay characteristic, the second delay characteristic, and the third delay characteristic includes a relationship between a repetition frequency of pulse laser light output from the laser system and a corresponding delay time from the output timing to a turn-on timing, and
the at least one output timing is corrected based on the repetition frequency.

16. The adjustment method of a laser system according to claim 13,
wherein each of the first delay characteristic, the second delay characteristic, and the third delay characteristic includes a relationship among a number of pulses from a first pulse of pulse laser light continuously output from the laser system, a repetition frequency of the pulse laser light, and a corresponding delay time from the output timing to a turn-on timing, and
the at least one output timing is corrected based on the number of pulses and the repetition frequency.

17. An electronic device manufacturing method, comprising:
generating pulse laser light using a laser system;
outputting the pulse laser light to an exposure apparatus; and
exposing a photosensitive substrate to the pulse laser light in the exposure apparatus to manufacture an electronic device,
the laser system including:
an oscillation-stage laser device including a first pulse compression circuit;
an amplification-stage laser device including a second pulse compression circuit; and
a processor configured to determine a timing difference from when a first switch included in the first pulse compression circuit and having a first delay characteristic is turned on until when a second switch included in the second pulse compression circuit and having a second delay characteristic is turned on, and control an output timing of each of a first oscillation trigger signal to be input to the first pulse compression circuit and a second oscillation trigger signal to be input to the second pulse compression circuit so that the oscillation-stage laser device and the amplification-stage laser device are synchronized with each other, and when one of the first switch and the second switch is replaced with a third switch having a third delay characteristic, correct the output timing of at least one of the first oscillation trigger signal and the second oscillation trigger signal to suppress change of the timing difference.

18. The electronic device manufacturing method according to claim 17,
wherein each of the first delay characteristic, the second delay characteristic, and the third delay characteristic includes a relationship between a number of pulses from a first pulse of the pulse laser light continuously output from the laser system and a corresponding delay time from the output timing to a turn-on timing, and
the at least one output timing is corrected based on the number of pulses.

19. The electronic device manufacturing method according to claim 17,
wherein each of the first delay characteristic, the second delay characteristic, and the third delay characteristic includes a relationship between a repetition frequency of the pulse laser light and a corresponding delay time from the output timing to a turn-on timing, and
the at least one output timing is corrected based on the repetition frequency.

20. The electronic device manufacturing method according to claim 17,
wherein each of the first delay characteristic, the second delay characteristic, and the third delay characteristic includes a relationship among a number of pulses from a first pulse of the pulse laser light continuously output from the laser system, a repetition frequency of the pulse laser light, and a corresponding delay time from the output timing to a turn-on timing, and
the at least one output timing is corrected based on the number of pulses and the repetition frequency.
